(19) United States
(12) Patent Application Publication
(10) Pub. No.: US 2024/0096905 A1
(43) Pub. Date: Mar. 21, 2024

(54) DISPLAY PANEL AND TILED DISPLAY SCREEN

(71) Applicant: Xiamen Extremely PQ Display Technology Co., Ltd., Xiamen (CN)

(72) Inventor: YONG FAN, Xiamen (CN)

(21) Appl. No.: 18/519,101

(22) Filed: Nov. 27, 2023

Related U.S. Application Data
(63) Continuation of application No. PCT/CN2022/071499, filed on Jan. 12, 2022.

(51) Int. Cl. H01L 27/12; H01L 25/16

(52) U.S. Cl. CPC H01L 27/124; H01L 25/167

(57) ABSTRACT

A display panel includes: a drive control circuit layer; micro light-emitting elements, disposed on the drive control circuit layer and electrically connected to the drive control circuit layer; an insulation layer, disposed on a side of the drive control circuit layer facing away from the micro light-emitting elements; a fanout wiring layer, disposed in the insulation layer and penetrating through the insulation layer so as to form electrical connections with the micro light-emitting elements and the drive control circuit layer; a patterned planarization layer, disposed on a side of the insulation layer facing away from the drive control circuit layer; and a bonding wire layer, disposed in through-holes of the patterned planarization layer and electrically connected to the fanout wiring layer, and being used for externally connecting a panel driver circuit. Moreover, a tiled display screen including display panels tiled together is also provided.

### CROSS-REFERENCE TO RELATED APPLICATION

This application is a continuation of International Application No. PCT/CN2022/071499, filed on Jan. 12, 2022, the disclosure of which is incorporated herein by reference in its entirety.

### TECHNICAL FIELD

The present disclosure relates to the field of display technologies, and particularly to a display panel, and a tiled display screen.

### BACKGROUND

A micro light-emitting diode (micro-LED) display panel has advantages of an organic light-emitting diode (OLED) display panel such as slim, flexible, shockproof, foldable, and meanwhile has advantages of long lifespan, ultra-low power consumption, high response speed and high transparency, and thus is regarded as the most potential new display technology in the next generation, and highly in line with the future development trend. It is worth mentioning that, a micro-LED chip used in the micro-LED display panel generally refers to a semiconductor light-emitting chip whose length, width and thickness are all less than 100 micrometres (pin), which typically includes an epitaxial structure whose growth substrate has been removed and without a support of a bonding substrate. The bonding substrate herein generally refers to a substrate that is connected to the epitaxial structure through a bonding process, such as a metal bonding process.

The existing micro-LED display panel needs a manner of printing wires on its lateral side surface to realize a bonding between a fanout wires for TFT transistors and a panel driver circuit with a chip-on-flex (COF), but the process is complex and costly. Moreover, the wires printed on the lateral side surface are exposed to the external environment, so that there are risks that the wires are scratched and extruded to be broken in an assembly process.

### SUMMARY

Aiming at at least some of the defects in the related art, an embodiment of the present disclosure provides a display panel. Specifically, the display panel includes, for example, a drive control circuit layer; micro light-emitting elements, disposed on the drive control circuit layer and electrically connected to the drive control circuit layer; an insulation layer, disposed on a side of the drive control circuit layer facing away from the micro light-emitting elements; a fanout wiring layer, disposed in the insulation layer and penetrating through the insulation layer, and electrically connected to the micro light-emitting elements and the drive control circuit layer individually; a patterned planarization layer, disposed on a side of the insulation layer facing away from the drive control circuit layer; and a bonding wire layer, disposed in through-holes of the patterned planarization layer to electrically connect the fanout wiring layer, and the bonding wire layer being configured (i.e., structured and arranged) to externally connect a panel driver circuit.

For the display panel provided by the above technical solution, by configuring the fanout wiring layer in the insulation layer and electrically connect to the micro light-emitting elements and the drive control circuit layer individually, and by configuring the bonding wire layer in the patterned planarization layer and electrically connect to the fanout wiring layer, it facilitates to externally connect a panel driver circuit through the bonding wire layer on the back side of the display panel, the problem in the related art that wires which need to be arranged/printed on the lateral side surface of the display panel are exposed to the external environment is avoided, the risks that the wires are scratched and extruded to be broken in an assembly process are reduced, and moreover the bonding wire layer and the fanout wiring layer are protected.

In an embodiment of the present disclosure, the bonding wire layer is a thick metal layer with a thickness greater than or equal to 1 micrometre.

In the above technical solution, by setting the bonding wire layer as the thick metal layer with the thickness greater than or equal to 1 micrometre, it can prevent the problem of poor contact when the bonding wire layer bonded with the panel driver circuit, and facilitates subsequent repair and detection works such as rework on the bonding wire layer.

In an embodiment of the present disclosure, the drive control circuit layer includes: a pixel driving circuit layer, disposed on a side of the insulation layer facing away from the patterned planarization layer, and including sub-pixel driving circuits electrically connected to the micro light-emitting elements respectively; and a second planarization layer, disposed on a side of the pixel driving circuit layer facing away from the insulation layer, and including first contact holes arranged corresponding to the sub-pixel driving circuits in a one-to-one manner and penetrating through the second planarization layer, the first contact holes having respective first connection metal layers disposed therein, and the micro light-emitting elements being electrically connected to the sub-pixel driving circuits through the first connection metal layers respectively.

In an embodiment of the present disclosure, each of the micro light-emitting elements includes a first electrode and a second electrode, and the first electrode is electrically connected to a corresponding one of the sub-pixel driving circuit through the first connection metal layer; the display panel is further disposed with second contact holes penetrating through both the second planarization layer and the pixel driving circuit layer, the second contact holes have respective second connection metal layers disposed therein, and the second electrode is electrically connected to the fanout wiring layer through the second connection metal layer.

In an embodiment of the present disclosure, the fanout wiring layer includes a data drive voltage line, a scan voltage line, a constant-current drive voltage line, and a reference voltage line; the data drive voltage line, the scan voltage line, the constant-current drive voltage line, and the reference voltage line are electrically connected to the drive control circuit layer and the micro light-emitting elements.

In an embodiment of the present disclosure, the sub-pixel driving circuit includes a first thin film transistor and a second thin film transistor; the first thin film transistor comprises a first gate, a first source, a first drain, and a first active layer; the second thin film transistor comprises a second gate, a second source, a second drain, and a second active layer; the first drain is electrically connected to the second gate, and the first electrode is electrically connected to the second drain through the first connection metal layer; the first gate is electrically connected to the scan voltage line, the first source is electrically connected to the data drive voltage line, the second source is electrically connected to the constant-current drive voltage line, and the second electrode is electrically connected to the reference voltage line through the second connection metal layer.

In an embodiment of the present disclosure, the drive control circuit layer further includes a light-shielding layer, and the light-shielding layer is disposed on a side of the second planarization layer facing away from the pixel driving circuit layer and located between the micro light-emitting elements and the second planarization layer.

In the above technical solution, by setting the light-shielding layer, light on the back side of the display panel does not reach a display area of the display panel, so that a contrast of the display panel can be increased.

In an embodiment of the present disclosure, the display panel further includes a protective layer, and the protective layer is disposed on a side of the patterned planarization layer facing away from the fanout wiring layer and exposes the bonding wire layer.

In the above technical solution, by setting the protective layer, it is beneficial for heat dissipation of the display panel and can protect the flatness and cleanliness of the back surface of the patterned planarization layer.

In an embodiment of the present disclosure, the patterned planarization layer is a multi-layered structure formed by an organic material layer and an inorganic material layer.

In the above technical solution, by setting the patterned planarization layer to be the multi-layered structure, it can increase adhesion of the bonding wire layer with the patterned planarization layer, and avoid an influence on the yield of the display panel caused by the peeling-off of the bonding wire layer.

In an embodiment of the present disclosure, the display panel further includes a printed circuit board and a chip-on-flex (COF) electrically connected to the printed circuit board, the COF is bonded to the bonding wire layer to thereby drive the micro light-emitting elements through the bonding wire layer and the fanout wiring layer. In addition, an embodiment of the present disclosure provides a tiled display screen. The tiled display screen includes, for example, a plurality of display panels, wherein each of the plurality of display panels is the display panel according to any one of the above embodiments; at least one conductive connecting member, wherein each the conductive connecting member includes a first connection end and a second connection end, the first connection end and the second connection end are bonded to the bonding wire layers of adjacent two display panels of the plurality of display panels, respectively; and a panel driver circuit, including a printed circuit board and at least one COF electrically connected to the printed circuit board, wherein each the COF is bonded to the bonding wire layer of a target display panel of the plurality of display panels.

Since any one display panel in the tiled display screen does not need to be provided with wires on the lateral side surface, no bright and dark lined during displaying after being tiled can be achieved, and thus a large-size tiled display screen without bright and dark line is realized.

In an embodiment of the present disclosure, the at least one conductive connecting member is a plurality of conductive connecting members, the plurality of display panels are divided into a plurality of groups of display panels, the display panels in the same group of display panels are sequentially connected through at least one of the plurality of conductive connecting members.

In an embodiment of the present disclosure, the at least one COF is a plurality of COFs, the plurality of display panels are divided into a plurality of groups of display panels, and the plurality of COFs are bonded to the bonding wire layers of respective edge-most display panels of the plurality of groups of display panels respectively.

In the above technical solution, by grouping the plurality of display panels, and bonding the plurality of COFs to the respective edge-most display panels in the plurality of groups of display panels, one group of display panels is driven by one COF, thereby saving the driving cost.

Sum up, the above technical solutions may have one or more advantages or benefits as follows. In one aspect, for the display panel according to any one embodiment of the present disclosure, by configuring the fanout wiring layer in the insulation layer and electrically connect to the micro light-emitting elements and the drive control circuit layer individually, and by configuring the bonding wire layer in the patterned planarization layer and electrically connect to the fanout wiring layer, it facilitates to externally connect a panel driver circuit through the bonding wire layer on the back side of the display panel; since it is externally connected to the panel driver circuit through the bonding wire layer on the back side of the display panel, the problem in the related art that wires which need to be arranged/printed on the lateral side surface of the display panel are exposed to the external environment is avoided, the risks that the wires are scratched and extruded to be broken in an assembly process are reduced, and moreover the bonding wire layer and the fanout wiring layer are protected. Moreover, by setting the bonding wire layer as a thick metal layer with a thickness greater than or equal to 1 micrometre, it can prevent the problem of poor contact when the bonding wire layer bonded with the panel driver circuit, and facilitates subsequent repair and detection works such as rework on the bonding wire layer. In addition, by setting the light-shielding layer, light on the back side of the display panel does not reach the display area of the display panel, so that a contrast of the display panel can be increased. Furthermore, by setting the protective layer, it is beneficial for heat dissipation of the display panel and can protect the flatness and cleanliness of the back surface of the patterned planarization layer. Finally, by setting the patterned planarization layer to be the multi-layered structure, it can increase adhesion of the bonding wire layer in the patterned planarization layer, and avoid an influence on the yield of the display panel caused by the peeling-off of the bonding wire layer. in another aspect, for the tiled display screen according to any one embodiment of the present disclosure, since any one display panel in the tiled display screen does not need to be provided with wires on the lateral side surface, no bright and dark lined during displaying after being tiled can be achieved, and thus a large-size tiled display screen without visible bright and dark line can be realized. Moreover, by grouping the plurality of display panels and bonding the plurality of COFs to the respective edge-most display panels in the plurality of groups of display panels, one group of display panels is driven by one COF, thereby saving the driving cost.

### BRIEF DESCRIPTION OF DRAWINGS

In order to more clearly illustrate technical solutions of embodiments of the present disclosure, the accompanying drawings used in the description of the embodiments will be briefly introduced below. Apparently, the accompanying drawings in the following description are only some embodiments of the present disclosure, and those skilled in the art can obtain other drawings according to these drawings without creative effort.

FIG. 1 illustrates a schematic structural view of a display panel according to a first embodiment of the present disclosure.

FIG. 2 illustrates a schematic structural view of another display panel according to the first embodiment of the present disclosure.

FIG. 3 illustrates a schematic structural view of a sub-pixel driving circuit according to the first embodiment of the present disclosure.

FIG. 4 illustrates a schematic structural view of still another display panel according to the first embodiment of the present disclosure.

FIG. 5 illustrates a schematic structural view of even still another display panel according to the first embodiment of the present disclosure.

FIG. 6 illustrates a schematic structural view of a tiled display screen according to a second embodiment of the present disclosure.

FIG. 7 illustrates a schematic structural view of a tiled display screen according to a third embodiment of the present disclosure.

FIG. 8 illustrates a schematic structural view of a tiled display screen according to a fourth embodiment of the present disclosure.

### DETAILED DESCRIPTION OF EMBODIMENTS

Technical solutions in embodiments of the present disclosure will be clearly and completely described below with reference to the accompanying drawings in the embodiments of the present disclosure. Apparently, the described embodiments are only some of embodiments of the present disclosure, not all of embodiments of the present disclosure. Based on the described embodiments in the present disclosure, all other embodiments obtained by those skilled in the art without creative effort are within the scope of protection of the present disclosure.

### First Embodiment

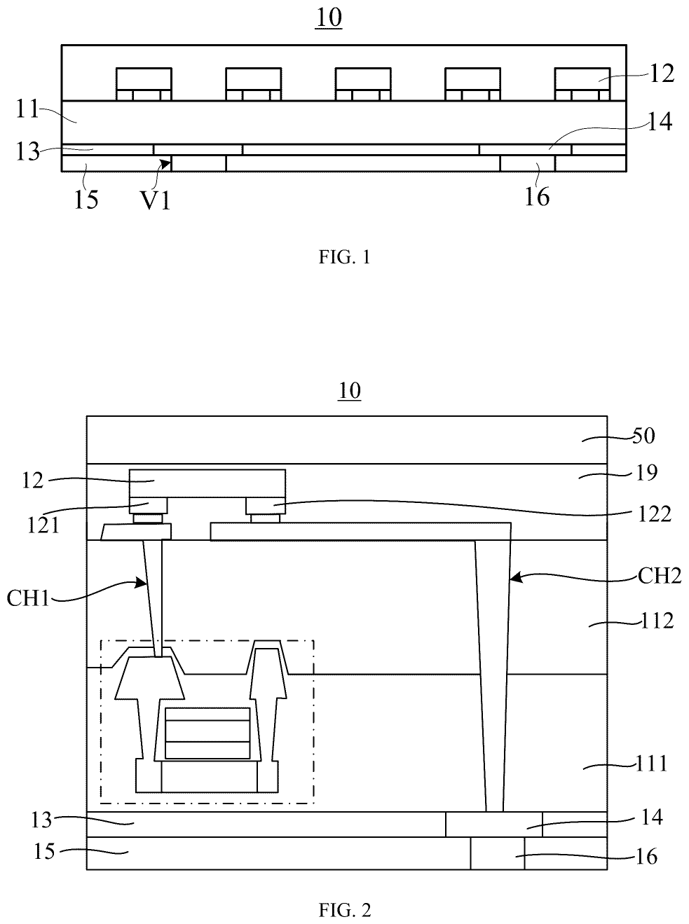

As illustrated in FIG. 1, the first embodiment of the present disclosure provides a display panel 10. The display panel 10 includes, for example, a drive control circuit layer 11, micro light-emitting elements 12, an insulation layer 13, a fanout wiring layer 14, a patterned planarization layer 15, and a bonding wire layer 16.

Specifically, the drive control circuit layer 11 is, for example, disposed with a pixel driving circuit for driving the micro light-emitting elements 12 to emit light. The micro light-emitting elements each are also referred to a micro light-emitting diode (Micro-LED) chip as an implementation; and a length, a width and a thickness of each the micro light-emitting element are, for example, all less than 100 micrometres. The micro light-emitting elements 12 are, for example, arranged on the drive control circuit layer 11 in rows and columns. The micro light-emitting elements 12 are electrically connected to the drive control circuit layer 11, for example, by binding, bonding or other manner, and the embodiment of the present disclosure is not limited to these. The micro light-emitting elements 12 arranged in rows and columns together constitute a display area of the display panel 10.

The insulation layer 13 is, for example, disposed on a side of the drive control circuit layer 11 facing away from the micro light-emitting elements 12. Herein, a material of the insulation layer 13 is, for example, silicon oxide, silicon nitride, or a combination thereof.

The fanout wiring layer 14 is, for example, disposed in the insulation layer 13 and penetrating through the insulation layer 13. Specifically, the fanout wiring layer 14 is, for example, formed by etching a metal thin film or a metal oxide thin film. For example, the metal thin film may be aluminum, molybdenum, copper, or the like; and the metal oxide thin film may be a transparent metal oxide thin film such as indium zinc oxide (IZO), indium gallium oxide (IGO), indium gallium zinc oxide (IGZO), indium gallium tin oxide (IGTO), or indium gallium zinc tin oxide (IGZTO), or may be other opaque metal oxide thin film; but the embodiments of the present disclosure are not limited to these. The fanout wiring layer 14 is, for example, electrically connected to the micro light-emitting elements 12 and the drive control circuit layer 11.

The patterned planarization layer 15 is, for example, disposed on a side of the insulation layer 13 facing away from the drive control circuit layer 11. The patterned planarization layer 15 is, for example, formed with through-holes V1, and the number of the through-holes V1 is, for example, multiple (i.e., more than one). The bonding wire layer 16 is, for example, disposed in the through-holes V1, and the bonding wire layer 16 is electrically connected to the fanout wiring layer 14. More specifically, the fanout wiring layer 14 extends, for example, partially into the through-holes V1, so that the through-holes V1 provide a place for the bonding wire layer 16 and the fanout wiring layer 14 to be electrically connected. The bonding wire layer 16 is configured (i.e., structured and arranged) to externally connect a panel driver circuit.

In the above-described technical solution, the fanout wiring layer is disposed in the insulation layer and electrically connected to the micro light-emitting elements and the drive control circuit layer individually, the bonding wire layer is disposed in the patterned planarization layer and electrically connected to the fanout wiring layer, which facilitates to externally connect a panel driver circuit through the bonding wire layer on the back side of the display panel, the problem in the related art that wires which need to be arranged/printed on the lateral side surface of the display panel are exposed to the external environment is avoided, the risks that the wires are scratched and extruded to be broken in an assembly process are reduced, and moreover the bonding wire layer and the fanout wiring layer are protected.

In some implementations, the bonding wire layer 16 is, for example, a thick metal layer with a thickness greater than or equal to 1 micrometre. The thick meta layer is, for example, a metal material with good electrical conductivity; for instance, the metal material is, for example, copper, molybdenum, aluminium, or other metal with good electrical conductivity. Herein, the thickness of the bonding wire layer 16 is set to be at least 1 micrometre, which can prevent the problem of poor contact when the bonding wire layer 16 bonded with the panel driver circuit, and facilitates subsequent repair and detection works such as rework on the bonding wire layer 16.

In some implementations, a material of the patterned planarization layer 15 is, for example, an organic material such as one or more of methyl methacrylate (MMA), polyimide (PI), BT (generally is an abbreviation of bismaleimide triazine) material, silicon oxide (SiOx), and silicon nitride (SiNx). For instance, the patterned planarization layer 15 is, for example, a single-layered organic material layer or a single-layered inorganic material layer, and a material of the single-layered organic or inorganic material layer is, for example, one of the above-mentioned materials of the patterned planarization layer. The patterned planarization layer 15 is, for example, a multi-layered structure instead, and the multi-layered structure is, for example, stacked organic material layers, stacked inorganic material layers, or alternately arranged inorganic material layers and organic material layers. By setting the patterned planarization layer 15 to be the multi-layered structure, which can increase adhesion of the bonding wire layer 16 in the through-holes V1 of the patterned planarization layer 15, and avoid an influence on the yield of the display panel 10 caused by the peeling-off of the bonding wire layer 16.

In some implementations, as illustrated in FIG. 2, the drive control circuit layer 11 includes, for example, a pixel driving circuit layer 111 and a second planarization layer 112. More specifically, the pixel driving circuit layer 111 is, for example, arranged on a side of the insulation layer 13 facing away from the patterned planarization layer 15. As seen from FIG. 2 through FIG. 4, it can be found that, the pixel driving circuit layer 111 includes, for example, sub-pixel driving circuits PXL. Each the sub-pixel driving circuit PXL is composed of, for example, thin film transistors (also referred to as transistors) Q1, Q2 electrically connected mutually and a storage capacitor Cst. Each the sub-pixel driving circuit PXL is electrically connected to the micro light-emitting element 12 correspondingly, and configured to drive the micro light-emitting element 12 to emit light. The second planarization layer 112 is, for example, disposed on a side of the pixel driving circuit layer 111 facing away from the insulation layer 13. The second planarization layer 112 is formed with first contact holes CH1. The first contact holes CH1 are, for example, arranged corresponding to the sub-pixel driving circuits PXL in a one-to-one manner. The first contact holes CH1 penetrate through the second planarization layer 112 above the sub-pixel driving circuits PXL, and contact with the sub-pixel driving circuits PXL respectively. First connection metal layers are disposed in the respective first contact holes CH1, and a side of the first contact holes CH1 facing towards the micro light-emitting elements 12 is correspondingly disposed with pixel electrodes, and the micro light-emitting elements 12 are electrically connected to the pixel electrodes respectively. The pixel electrode is electrically connected to a drain of the thin film transistor Q2 of the sub-pixel driving circuit PXL through the first connection metal layer in the first contact hole CH1, so that the micro light-emitting elements 12 are electrically connected to the sub-pixel driving circuits PXL through the respective first contact holes CH1, respectively.

In some implementations, as illustrated in FIG. 2 and FIG. 4, each of the micro light-emitting elements 12 includes, for example, a first electrode 121 (e.g., anode) and a second electrode 122 (e.g., cathode). The first electrode 121 is, for example, electrically connected to the drive control circuit layer 11. Specifically, the first electrode 121 is through the first contact hole CH1 corresponding thereto electrically connected to the sub-pixel driving circuit PXL corresponding to the first contact hole CH1. The display panel 10 is further disposed with second contact holes CH2 penetrating through the second planarization layer 112 and the pixel driving circuit layer 111, second connection metal layers are arranged in the respective second contact holes CH2, and the second electrode 122 is electrically connected to the fanout wiring layer 14 through the corresponding second connection metal layer in the second contact hole CH2.

In some implementations, the fanout wiring layer 14 includes, for example, functional lines. Specifically, the functional lines include, for example, a data drive voltage line 141 (also referred to as data line), a scan voltage line 142 (also referred to as gate line), constant-current drive voltage line 143 (also referred to as VDD line), and a reference voltage line 144 (also referred to as VSS line). The functional lines are arranged on the patterned planarization layer 15 and extend into the through-holes V1 to electrically connect the bonding wire layer 16. The fanout wiring layer 14 is electrically connected to signal input terminals of each the sub-pixel driving circuit PXL of the drive control circuit layer 11, and the micro light-emitting element 12 electrically connected to each the sub-pixel driving circuit PXL. Specifically, the VSS line is electrically connected to the second electrode 122 of the micro light-emitting element 12; and the VDD line, the gate line and the data line respectively are electrically connected to a source of the thin film transistor Q2, a gate of the thin film transistor Q1 and a source of the thin film transistor Q1 of the sub-pixel driving circuit PXL.

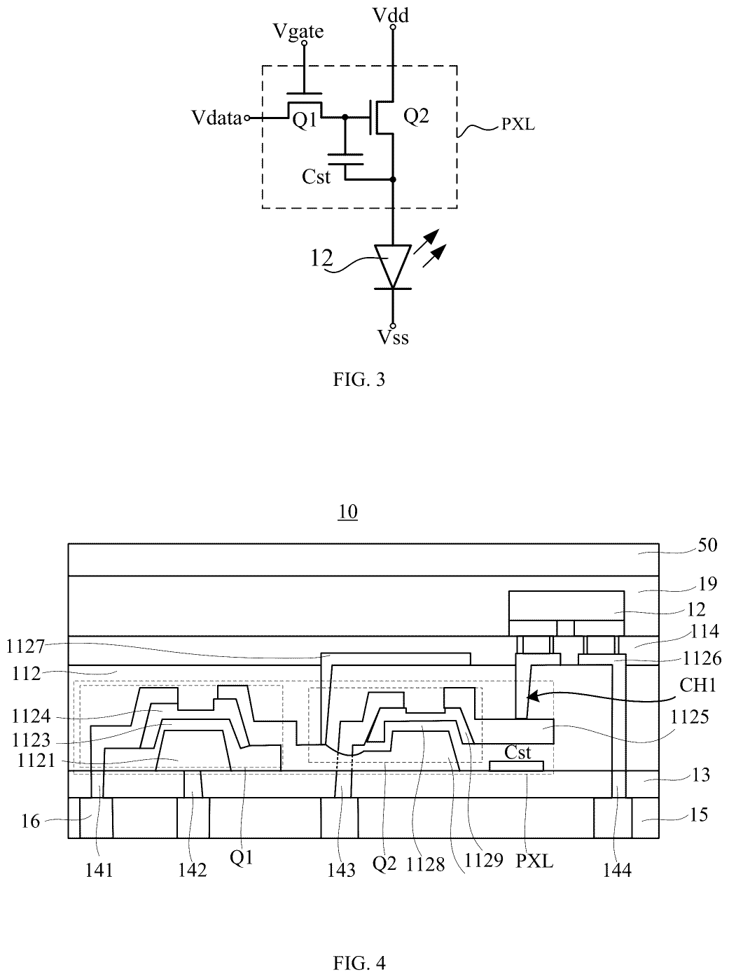

In some implementations, the display panel 10 according to the first embodiment of the present disclosure is an active matrix (AM) type display panel. As illustrated in FIG. 3 and FIG. 4, each the sub-pixel driving circuit PXL of the drive control circuit layer 11 is, for example, a 2T1C (two transistors and one capacitor) driving circuit. More specifically, as illustrated in FIG. 3, each the sub-pixel driving circuit PXL includes the transistor Q1, the transistor Q2 and the storage capacitor Cst electrically connected one another; and each the sub-pixel driving circuit PXL is electrically connected to the micro light-emitting element 12 correspondingly. The drain of the transistor Q2 is electrically connected to the anode of the micro light-emitting element 12, the cathode of the micro light-emitting element 12 is electrically connected to the VSS line to receive a reference voltage signal Vss delivered by the VSS line. The gate of the transistor Q1 is connected with the gate lien to receive a scan signal Vgate delivered by the gate line. The source of the transistor Q2 is connected with the VDD line to receive a power supply voltage signal Vdd delivered by the VDD line. Therefore, when the scan signal Vgate on the gate line is input, the transistor Q1 is turned on, the data signal Vdata on the data line is delivered to the gate of the transistor Q2 and meanwhile charges the storage capacitor Cst; and afterwards, the transistor Q2 is turned on, so that a driving current flows between the input terminal of power supply voltage signal Vdd and the input terminal of reference voltage signal Vss, the driving current flows through the micro light-emitting element 12, and the micro light-emitting element 12 emits light under the action of the driving current.

In some implementations, as illustrated in FIG. 4, the bonding wire layer includes, for example, bonding pads corresponding to the functional lines. The fanout wiring layer 14 is disposed in the insulation layer 13, and electrically connected to the bonding pads, the sub-pixel driving circuit PXL and the micro light-emitting elements 12 correspondingly. More specifically, the VSS line, the VDD line, the gate line, and the data line are electrically connected to the bonding pads of the bonding wire layer 16 correspondingly, and can be electrically connected with the signal input terminals of the sub-pixel driving circuits PXL of the drive control circuit layer 11.

In some implementations, single the sub-pixel driving circuit PXL includes the transistor Q1, the transistor Q2, and the storage capacitor Cst. As illustrated in FIG. 2 and FIG. 4, the drain of the transistor Q2 is electrically connected to the pixel electrode through the first contact hole CH1. More specifically, as illustrated in FIG. 4, the transistor Q1 includes a gate (hereinafter also referred to as first gate), a source (hereinafter also referred to as first source), a drain (hereinafter also referred to as first drain), a gate insulating layer (hereinafter also referred to as first gate insulating layer) 1123, and an active layer (hereinafter also referred to as first active layer) 1124. The first gate is disposed on a side of the insulation layer 13 facing away from the patterned planarization layer 15. The first gate insulating layer 1123 is disposed covering the first gate. The first active layer 1124 is disposed on a side of the first gate insulating layer 1123 facing away from the first gate. The first source and the first drain both are disposed on a side of the first active layer 1124 facing away from the first gate insulating layer 1123. The transistor Q2 includes a gate (hereinafter also referred to as second gate), a source (hereinafter also referred to as second source), a drain (hereinafter also referred to as second drain), a gate insulating layer (hereinafter also referred to as second gate insulating layer) 1128, and an active layer (hereinafter also referred to as second active layer) 1129. The second gate is disposed on the side of the insulation layer 13 facing away from the patterned planarization layer 15. The second gate insulating layer 1128 is disposed covering the second gate. The second active layer 1129 is disposed on a side of the second gate insulating layer 1128 facing away from the second gate. The second source and the second drain both are disposed on a side of the second active layer 1129 facing away from the second gate insulating layer 1128. The first drain of the transistor Q1 is electrically connected with the second gate of the transistor Q2. The storage capacitor Cst is arranged between the second gate and the second drain of the transistor Q2.

The first gate is formed, for example, by patterning and etching of a metal layer 1121, and the first gate is electrically connected to the scan voltage line (gate line) 142. The first source, the first drain and the second gate are formed, for example, by etching of a metal layer 1122; and the first source is, for example, electrically connected to the data drive voltage signal (data line) 141. The second drain and the second source are formed, for example, by etching of a metal layer 1125; and the second source is, for example, electrically connected to the constant-current drive voltage line (VDD line) 143. The second drain extends to a position where the first contact hole CH1 is located, so that the anode of the micro light-emitting element 12 is electrically connected to the drive control circuit layer 11 through the first connection metal layer in the first contact hole CH1. Materials of the metal layer 1121, the metal layer 1122 and the metal layer 1125 each are, for example, a metal or an alloy. For example, the materials of the metal layer 1121, the metal layer 1122 and the metal layer 1125 each may be a metal such as aluminum (Al), silver (Ag), tungsten (W), copper (Cu), nickel (Ni), chromium (Cr), molybdenum (Mo), titanium (Ti), platinum (Pt), tantalum (Ta) or neodymium (Nd), or an alloy thereof; but the embodiments of the present disclosure are not limited to these. Materials of the first gate insulating layer 1123 and the second gate insulating layer 1128 each may any one of SiOx, SiNx and SiNOx, but the embodiments of the present disclosure are not limited to these. Materials of the first active layer 1124 and the second active layer 1129 each may be an oxide semiconductor material, such as indium zinc oxide (IZO), indium gallium oxide (IGO), indium gallium zinc oxide (IGZO), indium gallium tin oxide (IGTO) or indium gallium zinc tin oxide (IGZTO), or each may be other material such as low-temperature polycrystalline silicon (LTPS); but the embodiments of the present disclosure are not limited to these.

In some implementations, the transistor Q2 further includes, for example, a top gate 1127. The top gate 1127 is, for example, electrically connected to the second gate of the transistor Q2. A projection of the top gate 1127 on the second gate of the transistor Q2 covers the second gate of the transistor Q2. By configuring the top gate 1127, it provides a top light-shielding effect to the transistor Q2, improves the mobility of the second active layer 1129, and stabilizes the output characteristics of the transistor Q2.

In some implementations the drive control circuit layer 11 includes, for example, a metal layer 1126. The metal layer 1126 is, for example, disposed on a side of the second planarization layer 112 facing away from the pixel driving circuit 111. The metal layer 1126 forms a pixel electrode and a common electrode. The pixel electrode is arranged on the side of the first contact hole CH1 facing towards the micro light-emitting element 12, the common electrode is electrically connected to the reference voltage line (VSS line) 144 through the second connection metal layer, and the first electrode 121 and the second electrode 122 of the micro light-emitting element 12 are electrically connected to the pixel electrode and the common electrode, respectively. In addition, the pixel electrode is through the first connection metal layer in the first contact hole CH1 corresponding thereto electrically connected to the second drain of the transistor Q2.

In some implementations, the drive control circuit layer 11 includes, for example, a light-shielding layer 114. The light-shielding layer 114 is, for example, disposed on a side of the second planarization layer 112 facing away from the pixel driving circuit layer 111; and the light-shielding layer 114 are located between the micro light-emitting elements 12 and the second planarization layer 112. The top gate 1127 is, for example, covered by the light-shielding layer. The light-shielding layer 114 is made of, for example, a black photoresist material. Herein, by setting the light-shielding layer 114, light on the back side of the display panel 10 does not reach the display area, so that a contrast of the display panel 10 can be increased.

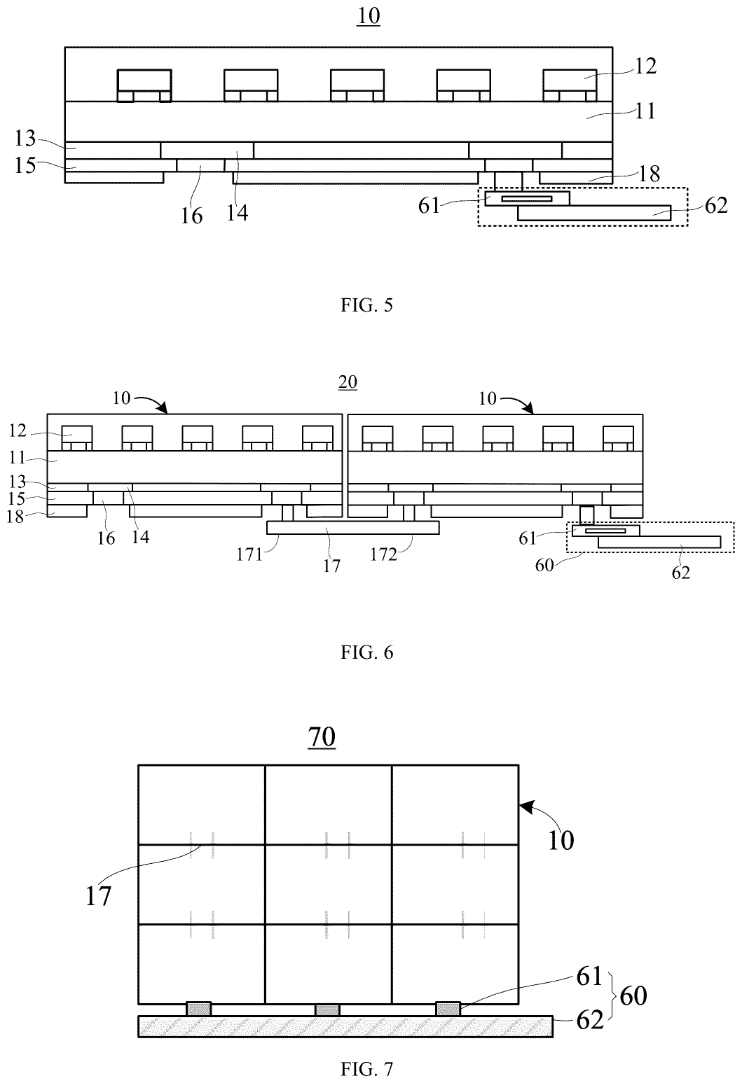

In an implementation, as illustrated in FIG. 5, the display panel further includes, for example, a protective layer 18. The protective layer 18 is made of a material such as a heat-dissipating copper foil, and disposed covering a side of the patterned planarization layer 15 facing away from the fanout wiring layer 14. The protective layer 18 exposes the bonding wire layer 16 in the through-holes V1 of the patterned planarization layer 15, so as to facilitate the bonding between the bonding wire layer 16 and a panel driver circuit. Moreover, by setting the protective layer 18, it is beneficial for heat dissipation of the display panel 10 and can protect the flatness and cleanliness of the back of the patterned planarization layer 15.

In some implementations, as illustrated in FIG. 5, the display panel 10 further includes, for example, a printed circuit board (PCB) 62 and a chip-on-flex (COF) 61 electrically connected to the printed circuit board 62. The printed circuit board 62 and the COF 61 constitute, for example, a panel driver circuit externally connected to the bonding wire layer 16. The panel driver circuit is, for example, configured to output driving signals to the drive control circuit layer 11 and the micro light-emitting elements 12, thereby realizing a display driving of the display panel 10. More specifically, the COF 61 is, for example, disposed with output terminals of driving signals such as a data drive voltage, a scan voltage, a constant-current drive voltage, and a reference voltage. The printed circuit board 62 is, for example, disposed with circuits such as a timing control circuit and a power supply for controlling the COF 61 to output the driving signals. Specifically, the COF 61 includes, for example, two connection ends; one of the connection ends is bonded to the printed circuit board 62, and the other one connection end is, for example, bonded to the bonding wire layer 16 of the display panel 10. More specifically, the COF 61 is bonded to the bonding wire layer 16 by, for example, a metal solder material, an ACF (anisotropic conductive film), or other material. By bonding the panel driver circuit on the bonding circuit layer 16 on the back side of the display panel 10, the formation of wires on the lateral side surface of the panel is avoided, and the problem in the related that the fanout wires need to be led out to the back side of the display panel by the wires on the lateral side surface is solved consequently.

As illustrated in FIG. 2 and FIG. 4, an encapsulation layer 19 is disposed on the drive control circuit layer 11. The encapsulation layer 19 for example covers the micro light-emitting elements 12. A material of the encapsulation layer 19 is, for example, a composite material such as a thermoplastic adhesive film or a polymer, which can effectively protect the micro-light-emitting elements 12 from water and oxygen in the outside. In an implementation, a protective cover 50 is, for example, disposed on a side of the encapsulation layer 19 facing away from the drive control circuit layer 11. The protective cover 50 is, for example, a transparent substrate that can effectively isolate water and oxygen to protect the display panel 10.

In addition, as seen from FIG. 4 in combination with FIGS. 1-2, in the illustrated implementation, the display panel 10 includes:

a drive control circuit layer 11, which includes sub-pixel driving circuits PXL (FIG. 4 only show one for illustrative purpose), the drive control circuit layer 11 is formed therein with first contact holes CH1 and second contact holes CH2, the first contact holes CH1 have respective first connection metal layers disposed therein, and the second contact holes CH2 have respective second connection metal layers disposed therein;

micro light-emitting elements 12, which are disposed on the drive control circuit layer 11, each of the micro light-emitting elements 12 includes a first electrode 121 and a second electrode 122, the first electrodes 121 of the micro light-emitting elements 12 respectively are electrically connected to the sub-pixel driving circuits PXL through the first connection metal layers in the respective first contact holes CH1;

an insulation layer 13, which is disposed on a side of the drive control circuit layer 11 facing away from the micro light-emitting elements 12;

a fanout wiring layer 14, which is disposed in the insulation layer 13 and penetrating through the insulation layer 13 and thus surrounded (e.g., encircled) by the insulation layer 13, the fanout wiring layer 14 is in direct metal-to-metal contact with the sub-pixel driving circuits PXL to form electrical connection, and further is electrically connected to the second electrodes 122 of the micro light-emitting elements 12 through the second connection metal layers in the respective second contact holes CH2;

a patterned planarization layer 15, which is disposed on a side of the insulation layer 13 facing away from the drive control circuit layer 11; and

a bonding wire layer 16, which is disposed in through-holes V1 of the patterned planarization layer 15, the bonding wire layer 16 is electrically connected to the fanout wiring layer 14, e.g., in direct metal-to-metal contact with the fanout wiring layer 14 to form electrical connection, and the bonding wire layer 16 is configured to be externally connected with a panel driver circuit.

Moreover, in an illustrated implementation, as shown in FIG. 4 in combination with FIG. 2, the fanout wiring layer 14 includes a data drive voltage line 141, a scan voltage line 142, a constant-current drive voltage line 143, and a reference voltage line 144; the data drive voltage line 141, the scan voltage line 142 and the constant-current drive voltage line 143 are in direct metal-to-metal contact with each of the sub-pixel driving circuits PXL; and the reference voltage line 144 is electrically connected to the second electrode 122 of each of the micro light-emitting elements 12 through the second connection metal layer in the second contact hole CH2.

In summary, the display panel according to the first embodiment of the present disclosure may have the following beneficial effects: by configuring the fanout wiring layer in the insulation layer and electrically connect to the micro light-emitting elements and the drive control circuit layer individually, and by configuring the bonding wire layer in the patterned planarization layer and electrically connect to the fanout wiring layer, it facilitates to externally connect a panel driver circuit through the bonding wire layer on the back side of the display panel; owing to the display panel is externally connected to the panel driver circuit through the bonding wire layer on its back side, the problem in the related art that wires which need to be arranged on the lateral side surface of the display panel are exposed to the external environment is avoided, the risks that the wires are scratched and extruded to be broken in an assembly process are reduced, and moreover the bonding wire layer and the fanout wiring layer are protected. Moreover, by setting the bonding wire layer as a thick metal layer with a thickness greater than or equal to 1 micrometre, it can prevent the problem of poor contact when the bonding wire layer bonded with the panel driver circuit, and facilitates subsequent repair and detection works such as rework on the bonding wire layer. In addition, by setting the light-shielding layer, light on the back side of the display panel does not reach a display area of the display panel, so that a contrast of the display panel can be increased. Furthermore, by setting the protective layer, it is beneficial for heat dissipation of the display panel and can protect the flatness and cleanliness of the back surface of the patterned planarization layer. Finally, by setting the patterned planarization layer to be the multi-layered structure, it can increase adhesion of the bonding wire layer with the patterned planarization layer, and avoid an influence on the yield of the display panel caused by the peeling-off of the bonding wire layer.

### Second Embodiment

As illustrated in FIG. 6, the second embodiment of the present disclosure provides a tiled display screen 20. The tiled display screen 20 includes: multiple (FIG. 6 shows two only as an example) display panels 10 tiled together, a panel driver circuit 60, and a conductive connecting member 17.

As seen from FIG. 6, the two display panels 10 are tiled side by side and electrically connected by the conductive connecting member 17. More specifically, each the display panel 10 includes, for example, a drive control circuit layer 11, micro light-emitting elements 12, an insulation layer 13, a fanout wiring layer 14, a patterned planarization layer 15, and a bonding wire layer 16.

In some implementations, the patterned planarization layer 15 is, for example, disposed with through-holes V1 (referring to FIG. 1), the bonding wire layer 16 is, for example, disposed in the through-holes V1. More specifically, the display panels 10 each include, for example, the fanout wiring layer 14 and the bonding wire layer 16. The panel driver circuit 60 includes, for example, a printed circuit board 63 and a COF 61. Detail structures of the above-mentioned various layers and components in the second embodiment and connection relationships thereof can refer to the above first embodiment, and thus will not be repeated herein.

In an implementation, the conductive connecting member 17 is, for example, a flexible circuit board, a connector assembly, or other component capable of realizing an electrically conductive connection. In an illustrated implementation, the conductive connecting member 17 includes a first connection end 171 and a second connection end 172. The first connection end 171 and the second connection end 172 are bonded to the bonding wire layers 16 of the two adjacently tiled display panels 10, respectively. Specifically, the first connection end 171 is bonded to the bonding wire layer 16 of one of the two display panels 10, and the second connection end 172 is bonded to the bonding wire layer 16 of the adjacent one of the two display panels 10.

In some implementations, the panel driver circuit 60 includes, for example, the printed circuit board 62 and the COF 61 electrically connected to the printed circuit board 62. The COF 61 is, for example, disposed with output terminals of driving signals such as a data drive voltage, a scan voltage, a constant-current drive voltage, and a reference voltage. The printed circuit board 62 is, for example, disposed with circuits such as a timing control circuit and a power supply for controlling the COF 61 to output the driving signals. Specifically, the COF 61 includes, for example, two connection ends; one the connection end is bonded to the printed circuit board 62, and the other connection end is, for example, bonded to the bonding wire layer 16 of a target display panel of the two display panels 10. More specifically, the COF 61 is bonded to the bonding wire layer 16 by, for example, a metal solder material, an ACF, or other material.

In some implementations, the display panels 10 of the tiled display screen 20 each include, for example, a protective layer 18. The protective layer 18 is arranged on a side of the patterned planarization layer 15 facing away from the fanout wiring layer 14 in each the display panel 10. The protective layer 18 exposes the bonding wire layer 16, which facilitates a bonding between the panel driver circuit 60 and the bonding wire layer 16.

For each the display panel in the tiled display screen according to the second embodiment of the present disclosure, since there is no need of forming the wires on the lateral side surface of the display panel as the related art, a gap between the two display panels can be flexibly adjusted according to different use situations of the tiled display screen. As a result, a pixel distance between adjacent two edge-most micro light-emitting elements of the two display panels can be equal to a pixel distance between two micro light-emitting elements 12 of any one of the display panels, thereby achieving a tiling display of no bright and dark line.

### Third Embodiment

In order to meet the requirement of large-size tiled display screen, the third embodiment of the present disclosure provides a tiled display screen 70. As illustrated in FIG. 7, the tiled display screen 70 includes, for example, display panels 10, a panel driver circuit 60, and conductive connecting members 17.

Specifically, the display panels 10 being nine in number is taken as an example for detail description. The nine display panels are tiled together and connected by the conductive connecting members 17 to form a tiled display screen 70 with three rows and three columns. Each the display panel 10 includes, for example, a drive control circuit layer, micro light-emitting elements, an insulation layer, a fanout wiring layer, a patterned planarization layer, and a bonding wire layer. Specific materials and connection relationships of the drive control circuit layer, the micro light-emitting elements, the insulating layer, the fanout wiring layer, the patterned planarization layer, and the bonding wire layer mentioned above can be referred to the first embodiment, and thus will not be repeated herein. The panel driver circuit 60 includes, for example, a printed circuit board 62 and COFs 61. The nine display panels 10 are divided into, for example, three groups of display panels. Each group of display panels is, for example, one row or one column of display panels. The number of the COFs 61 is corresponding to, for example, the group number of the display panels, and thus the number of the COFs 61 may be three. Each group of display panels are sequentially connected through the conductive connecting members 17. The three COFs 61 are correspondingly bonded to the bonding wire layers of target display panels of the three groups of the display panels. In a preferred implementation, each the COF 61 is correspondingly bonded to the bonding wire layer of an edge-most display panel in one group of display panels. As illustrated in FIG. 7, the three COFs 61 are respectively bonded to edge-most display panels of the three columns of display panels.

In an implementation, each the conductive connecting member 17 is, for example, a flexible circuit board, a connector assembly, or other component capable of realizing an electrically conductive connection. The number of the conductive connecting members 17 is, for example, six; and each of which is bonded to the bonding wire layers of each two adjacent display panels arranged in one column. More specifically, the three display panels 10 in each group of display panels are sequentially connected through the conductive connecting members 17, so that each the COF 61 controls multiple display panels in a corresponding one group of display panels, thereby achieving the panel driver circuit 60 drives multiple display panels 10. When a larger tiled display screen is needed, the driving of the large tiled display screen can be realized only by adding COFs corresponding to the group number of the display panels and the conductive connecting members sequentially connecting two adjacent display panels in each group, thereby saving the driving cost.

### Fourth Embodiment

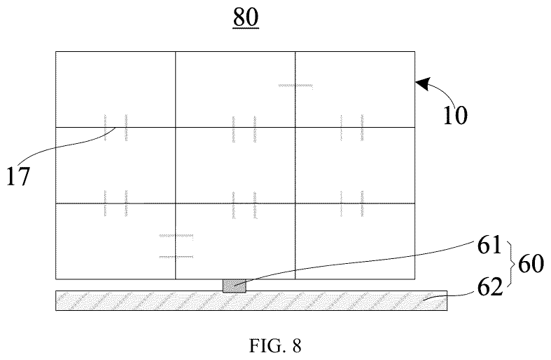

As illustrated in FIG. 8, the fourth embodiment of the present disclosure provides a tiled display screen 80. The tiled display screen 10 includes, for example, display panels 10, a panel driver circuit 60, and conductive connecting members 17.

Specifically, each display panel of the display panels 10 includes, for example, a drive control circuit layer, micro light-emitting elements, an insulation layer, a fanout wiring layer, a patterned planarization layer, and a bonding wire layer. Specific materials and connection relationships of the drive control circuit layer, the micro light-emitting elements, the insulation layer, the fanout wiring layer, the patterned planarization layer, and the bonding wire layer mentioned above can be referred to the first embodiment, and thus will not be repeated herein.

In an implementation, each the conductive connecting member 17 is, for example, a flexible circuit board, a connector assembly, or other component capable of realizing an electrically conductive connection. The panel driver circuit 60 includes, for example, a printed circuit board 62 and a COF 61. The COF 61 is boned between the printed circuit board 62 and one of the display panels 10. More specifically, the COF 61 is bonded to the bonding wire layer of any one edge-most display panel in the tiled display screen 80, and since the display panels 10 mutually are electrically connected, single the COF 61 under the driving of the printed circuit board 62 can send driving signals to the whole tiled display screen 80 through the bonding wire layer bonded thereto, thereby achieving a tiling display of the tiled display screen 80.

It can be understood that, the connection manner of the conductive connecting members 17 as illustrated in FIG. 8 only is an illustrative connection manner, and any connection manner of the conductive connecting members that can realize mutual conduction/connection among the display panels can be employed. In addition, for the tiled display screen according to the fourth embodiment of the present disclosure, when the number of the display panels to be tiled is large, the number of the COF 61 in the panel driver circuit 60 can be correspondingly increased according to the connection relationship between the conductive connecting members 17 and the display panels 10.

In summary, in the large-size tiled display screen without visible bright and dark line during displaying according to the fourth embodiment of the present disclosure, the display panels tiled together are electrically connected with each other by using the conductive connecting members, so that the whole tiled display screen can be driven by bonding the panel driver circuit 60 to the bonding wire layer of any one of the display panels, which can further save the driving cost.

In addition, it should be understood that, the foregoing embodiments are only exemplary descriptions of the present disclosure, and the technical solutions of the described embodiments can be combined and used arbitrarily on the premise that the technical features do not conflict, the structures do not contradict, and the purpose of the present disclosure is not violated.

Finally, it should be noted that, the foregoing embodiments are merely used to illustrate the technical solutions of the present disclosure, not to limit them. Although the present disclosure has been described in detail with reference to the foregoing embodiments, those skilled in the art should understand that the technical solutions described in the foregoing embodiments can still be modified, or some of the technical features thereof can be equivalently replaced; and these modifications or replacements do not make the essence of the corresponding technical solutions deviate from the spirit and scope of the technical solutions of the embodiments of the present disclosure.

What is claimed is:

1. A display panel, comprising:
a drive control circuit layer;
micro light-emitting elements, disposed on the drive control circuit layer and electrically connected to the drive control circuit layer;
an insulation layer, disposed on a side of the drive control circuit layer facing away from the micro light-emitting elements;
a fanout wiring layer, disposed in the insulation layer and penetrating through the insulation layer, wherein the fanout wiring layer is electrically connected to the micro light-emitting elements and the drive control circuit layer individually;
a patterned planarization layer, disposed on a side of the insulation layer facing away from the drive control circuit layer; and
a bonding wire layer, disposed in through-holes of the patterned planarization layer to electrically connect the fanout wiring layer, wherein the bonding wire layer is configured to externally connect a panel driver circuit.

2. The display panel as claimed in claim 1, wherein the bonding wire layer is a thick metal layer with a thickness greater than or equal to 1 micrometre.

3. The display panel as claimed in claim 1, wherein the drive control circuit layer comprises:
a pixel driving circuit layer, disposed on a side of the insulation layer facing away from the patterned planarization layer, wherein the pixel driving circuit layer comprises sub-pixel driving circuits electrically connected to the micro light-emitting elements respectively; and
a second planarization layer, disposed on a side of the pixel driving circuit layer facing away from the insulation layer, wherein the second planarization layer comprises first contact holes arranged corresponding to the sub-pixel driving circuits in a one-to-one manner and penetrating through the second planarization layer, the first contact holes have respective first connection metal layers disposed therein, and the micro light-emitting elements are electrically connected to the sub-pixel driving circuits through the first connection metal layers respectively.

4. The display panel as claimed in claim 3, wherein each of the micro light-emitting elements comprises a first electrode and a second electrode, and the first electrode is electrically connected to a corresponding one of the sub-pixel driving circuit through the first connection metal layer;
wherein the display panel is further disposed with second contact holes penetrating through both the second planarization layer and the pixel driving circuit layer, the second contact holes have respective second connection metal layers disposed therein, and the second electrode is electrically connected to the fanout wiring layer through the second connection metal layer.

5. The display panel as claimed in claim 4, wherein the fanout wiring layer comprises a data drive voltage line, a scan voltage line, a constant-current drive voltage line, and a reference voltage line; the data drive voltage line, the scan voltage line, the constant-current drive voltage line, and the reference voltage line are electrically connected to the drive control circuit layer and the micro light-emitting elements.

6. The display panel as claimed in claim 5, wherein the sub-pixel driving circuit comprises a first thin film transistor and a second thin film transistor; the first thin film transistor comprises a first gate, a first source, a first drain, and a first active layer; the second thin film transistor comprises a second gate, a second source, a second drain, and a second active layer; the first drain is electrically connected to the second gate, and the first electrode is electrically connected to the second drain through the first connection metal layer; the first gate is electrically connected to the scan voltage line, the first source is electrically connected to the data drive voltage line, the second source is electrically connected to the constant-current drive voltage line, and the second electrode is electrically connected to the reference voltage line through the second connection metal layer.

7. The display panel as claimed in claim 3, wherein the drive control circuit layer further comprises a light-shielding layer, and the light-shielding layer is disposed on a side of the second planarization layer facing away from the pixel driving circuit layer and located between the micro light-emitting elements and the second planarization layer.

8. The display panel as claimed in claim 1, wherein the display panel further comprises a protective layer, and the protective layer is disposed on a side of the patterned planarization layer facing away from the fanout wiring layer and exposes the bonding wire layer.

9. The display panel as claimed in claim 1, wherein the patterned planarization layer is a multi-layered structure formed by an organic material layer and an inorganic material layer.

10. The display panel as claimed in claim 1, wherein the display panel further comprises a printed circuit board and a chip-on-flex (COF) electrically connected to the printed circuit board, the COF is bonded to the bonding wire layer to thereby drive the micro light-emitting elements through the bonding wire layer and the fanout wiring layer.

11. A tiled display screen, comprising:
a plurality of display panels tiled together, wherein each of the plurality of display panels is the display panel as claimed in claim 1;
at least one conductive connecting member, wherein each the conductive connecting member comprises a first connection end and a second connection end, the first connection end and the second connection end are bonded to the bonding wire layers of adjacent two display panels of the plurality of display panels, respectively; and
a panel driver circuit, comprising a printed circuit board and at least one COF electrically connected to the printed circuit board, wherein each the COF is bonded to the bonding wire layer of a target display panel of the plurality of display panels.

12. The tiled display screen as claimed in claim 11, wherein the at least one conductive connecting member is a plurality of conductive connecting members, the plurality of display panels are divided into a plurality of groups of display panels, the display panels in the same group of display panels are sequentially connected through at least one of the plurality of conductive connecting members.

13. The tiled display screen as claimed in claim 11, wherein the at least one COF is a plurality of COFs, the plurality of display panels are divided into a plurality of groups of display panels, and the plurality of COFs are bonded to the bonding wire layers of respective edge-most display panels of the plurality of groups of display panels respectively.

14. A display panel, comprising:
a drive control circuit layer, comprising sub-pixel driving circuits, wherein the drive control circuit layer is formed therein with first contact holes and second contact holes, the first contact holes have respective first connection metal layers disposed therein, and the second contact holes have respective second connection metal layers disposed therein;
micro light-emitting elements, disposed on the drive control circuit layer, wherein each of the micro light-emitting elements comprises a first electrode and a second electrode, the first electrodes of the micro light-emitting elements respectively are electrically connected to the sub-pixel driving circuits through the first connection metal layers in the respective first contact holes;
an insulation layer, disposed on a side of the drive control circuit layer facing away from the micro light-emitting elements;
a fanout wiring layer, disposed in the insulation layer and penetrating through the insulation layer and thus surrounded by the insulation layer, wherein the fanout wiring layer is in direct metal-to-metal contact with the sub-pixel driving circuits to form electrical connection, and further is electrically connected to the second electrodes of the micro light-emitting elements through the second connection metal layers in the respective second contact holes;
a patterned planarization layer, disposed on a side of the insulation layer facing away from the drive control circuit layer; and
a bonding wire layer, disposed in through-holes of the patterned planarization layer, wherein the bonding wire layer is in direct metal-to-metal contact with the fanout wiring layer to form electrical connection, and the bonding wire layer is configured to be externally connected with a panel driver circuit.

15. The display panel as claimed in claim 14, wherein the bonding wire layer is a thick metal layer with a thickness greater than or equal to 1 micrometre.

16. The display panel as claimed in claim 14, wherein the fanout wiring layer comprises a data drive voltage line, a scan voltage line, a constant-current drive voltage line, and a reference voltage line; the data drive voltage line, the scan voltage line and the constant-current drive voltage line are in direct metal-to-metal contact with each of the sub-pixel driving circuits; and the reference voltage line is electrically connected to the second electrode of each of the micro light-emitting elements through the second connection metal layer in the second contact hole.

17. The display panel as claimed in claim 14, wherein the display panel further comprises a protective layer, and the protective layer is disposed on a side of the patterned planarization layer facing away from the fanout wiring layer and exposes the bonding wire layer.

18. The display panel as claimed in claim 14, wherein the patterned planarization layer is a multi-layered structure formed by stacked organic material layers, or stacked inorganic material layers, or alternately stacked an organic material layer and an inorganic material layer.

19. A tiled display screen, comprising:
display panels tiled together, wherein each of the display panels comprises:
a drive control circuit layer, comprising sub-pixel driving circuits, wherein the drive control circuit layer is formed therein with first contact holes and second contact holes, the first contact holes have respective first connection metal layers disposed therein, and the second contact holes have respective second connection metal layers disposed therein;
micro light-emitting elements, disposed on the drive control circuit layer, wherein a length, a width and a thickness of each of the micro light-emitting elements each are less than 100 micrometres, each of the micro light-emitting elements comprises a first electrode and a second electrode, the first electrodes of the micro light-emitting elements respectively are electrically connected to the sub-pixel driving circuits through the first connection metal layers in the respective first contact holes;
an insulation layer, disposed on a side of the drive control circuit layer facing away from the micro light-emitting elements;
a fanout wiring layer, disposed in the insulation layer and penetrating through the insulation layer and thus encircled by the insulation layer, wherein the fanout wiring layer is in direct metal-to-metal contact with the sub-pixel driving circuits to form electrical connection, and further is electrically connected to the second electrodes of the micro light-emitting elements through the second connection metal layers in the respective second contact holes;
a planarization layer, disposed on a side of the insulation layer facing away from the drive control circuit layer; and
a bonding wire layer, disposed in through-holes of the patterned planarization layer, wherein the bonding wire layer is electrically connected to the fanout wiring layer, and the bonding wire layer is configured to be externally connected with a panel driver circuit;
conductive connecting members, wherein each of the conductive connecting members comprises a first connection end and a second connection end, the first connection end and the second connection end are bonded to the bonding wire layers of adjacent two of the display panels, respectively; and
a panel driver circuit, comprising a printed circuit board and at least one COF electrically connected to the printed circuit board, wherein each the COF is bonded to the bonding wire layer of an edge-most display panel of the display panels.

20. The tiled display screen as claimed in claim 19, wherein the bonding wire layer is a thick metal layer with a thickness greater than or equal to 1 micrometre; and
wherein the fanout wiring layer comprises a data drive voltage line, a scan voltage line, a constant-current drive voltage line, and a reference voltage line; the data drive voltage line, the scan voltage line and the constant-current drive voltage line are in direct metal-to-metal contact with each of the sub-pixel driving circuits; and the reference voltage line is electrically connected to the second electrode of each of the micro light-emitting elements through the second connection metal layer in the second contact hole.
